(19) United States
(12) Patent Application Publication
(10) Pub. No.: US 2017/0032934 A1
(43) Pub. Date: Feb. 2, 2017

(54) GAS DISTRIBUTION APPARATUS IN A VACUUM CHAMBER, COMPRISING A GAS CONDUCTING DEVICE

(71) Applicant: BÜHLER ALZENAU GMBH, Alzenau (DE)

(72) Inventor: Jörg DUGGEN, Goldbach (DE)

(73) Assignee: BÜHLER ALZENAU GMBH, Alzenau (DE)

(21) Appl. No.: 15/302,527

(22) PCT Filed: Mar. 31, 2015
(86) PCT No.: PCT/EP2015/057115

§ 371 Date: Oct. 7, 2016

(30) Foreign Application Priority Data
Apr. 9, 2014 (DE) 10 2014 105 080.0

(51) Int. Cl. H01J 37/32; C23C 16/455

(52) U.S. Cl. CPC H01J 37/3244; C23C 16/45578; H01J 2237/006; H01J 2237/332

(57) ABSTRACT

A gas distribution apparatus in a vacuum chamber includes a gas conducting device that includes at least one gas duct equipped with nozzles from which gas can be distributed into the vacuum chamber, and a gas supplying device which allows gas to be supplied to the gas conducting device. The at least one gas duct is formed by a part designed as a single-piece hollow profile. The part designed as a single-piece hollow profile also forms at least one gas supply channel of the gas supplying device.

### BACKGROUND AND SUMMARY

The invention relates to a gas distribution apparatus in a vacuum chamber, comprising a gas conducting device, particularly a device for depositing thin layers onto a substrate using the cathode sputtering method.

A device for depositing thin layers onto a substrate using the cathode sputtering method in a vacuum chamber through which the substrate to be coated can be moved is known from EP 0 441 253 B1. A diaphragm is arranged between a cathode to be sputtered and an anode, wherein the substrate plane extends underneath the anode. Hollow profiles comprising ducts, held by the wall of the vacuum chamber and carrying a flow of a temperature control medium and a process gas, are provided parallel to the cathode and in the region between the cathode and the anode. Said ducts comprise openings for the process gas which extend transversely to the longitudinal axis of the ducts and allow the exit of the process gas into the vacuum chamber.

The temperature control medium and the process gas are guided in ducts formed by an integral component configured as a hollow profile, wherein the openings for the exit of the gas extend transversely to the longitudinal axis of the ducts. The device comprises a hollow profile which is characterized by a rectangular cross section with rounded corners. This profile has distinct and easily accessible contact points and allows the connection of temperature control medium and process gas outside the vacuum chamber.

It is desirable to create a gas distribution apparatus of a vacuum chamber which is of a simple and inexpensive design and allows, above all, the reliable and safe distribution of gases in a vacuum chamber.

According to one aspect of the invention, the invention relates to a gas distribution apparatus of a vacuum chamber comprising a gas conducting device which includes at least one gas carrying duct, which comprises nozzles from which gas can be distributed into the vacuum chamber, and a gas supplying device which allows gas to be supplied to the gas conducting device, wherein the at least one gas carrying duct us formed by a single-piece component that is designed as a hollow profile. The vacuum chamber is configured and set up for depositing thin layers onto substrates. It is understood that the invention also includes embodiments in which multiple components designed as hollow profiles are provided.

It is proposed that the single-piece component designed as a hollow profile forms at least one gas supplying duct (also called a gas line in prior art) of the gas supplying device. Such a hollow profile can cost-effectively be produced as an extruded section, for example from aluminum. The at least one gas supply duct is therefore a part of the extruded section, or the extruded section includes the at least one gas supply duct. It is understood that multiple gas supply ducts or gas lines can be parts of the extruded section.

The solution according to the invention of a gas distribution apparatus thus allows a simplification and improvement of the gas distribution apparatus, particularly for deposition onto thin substrates in a vacuum chamber using the cathode sputtering method. The gas distribution apparatus allows the integration of various functional parts, gas carrying duct and gas supplying device, into a special component. The gas distribution apparatus can be produced in a simplified manner by selecting a suitable cross section of a hollow profile, particularly a hollow aluminum profile. Optimization of a gas distribution apparatus for economic reasons is possible in this way. The number of requited components can be considerably reduced, which allows shorter assembly times of a deposition apparatus in a vacuum chamber.

The solution according to the invention of a gas distribution apparatus thus avoids disadvantages, e.g. that separate, multi-piece pipelines or gas lines are used to supply and return a gaseous medium and to supply process gas, which make it very susceptible to malfunctions and expensive in production and maintenance. Such pipelines include bends, windings, screwed connections and solder joints, which are in a vacuum under the regular operating conditions of the apparatus, and this may result in hairline cracks and leaks in the pipelines under the additional influence of process-related heat. These leaks first of all impair the quality of the deposited layers, such as the adhesive power of the layer to be deposited onto the substrate in a cathode sputtering or chemical gas vapor deposition (CVD) process, and can subsequently result in a total breakdown of the entire plant, which is always associated with considerable effort and high cost.

According to an advantageous other aspect of the invention, a gas distribution apparatus of a vacuum chamber comprising a gas conducting device can include at least one main duct with main duct nozzles from which main gas can be distributed into the vacuum chamber, and at least one tuning duct with tuning duct nozzles from which tuning gas can be distributed into the vacuum chamber. The vacuum chamber is configured and set up for depositing thin layers onto substrates.

Furthermore, the gas distribution apparatus comprising a gas supplying device can be configured with at least one main gas supply duct (main gas line), by means of which the main gas is supplied to the main duct, and with at least one tuning gas supply duct, by means of which tuning gas can be supplied to the tuning duct. The at least one main duct can further be formed by a component designed as a single-piece hollow profile. Such a hollow profile can cost-effectively be produced as an extruded section, for example from aluminum. Advantageously, the at least one main gas supply duct and/or the at least one tuning gas supply duct can also be formed by the component designed as a single-piece hollow profile or extruded section, respectively. The main process gas needed for the cathode sputtering process, such as argon or nitrogen, can be used as the so-called main gas.

Gases that can be considered for use as tuning gases include such gases that are essential for forming deposition materials to be deposited onto thin substrates in the cathode sputtering process, such as specific elements for forming chemical compounds. Other gases, such as additional inert gases that can be used for reducing the kinetic energy of ions in the cathode sputtering plasma can be supplied to the vacuum chamber as tuning eases in the gas distribution apparatus.

The at least one tuning duct may expediently be formed by the component designed as a single-piece hollow profile, particularly as an extruded section. In this way, a complex gas distribution apparatus can be produced in a particularly economical manner through high manufacturing flexibility. The invention also includes the case in which two hollow profiles, a first one for the main duct and a second one for the tuning duct, are used.

In an advantageous embodiment, the at least one tuning duct can include multiple chamber-like segments arranged one after the other along a longitudinal extension of the duct. Such an arrangement has the advantage that the tuning gases can be introduced into the various regions attic vacuum chamber in a targeted manner to achieve completely different deposition conditions at different spots while depositing onto a substrate. In this way, different deposition parameters or even different materials can be used at different spots. It is also possible to achieve different layer thicknesses or different layer properties in an inexpensive manner. The gas distribution apparatus can be designed for a larger number of segments depending on the requirements to be met by the layer distribution.

At least two consecutive segments may expediently comprise a common partition wall. Such segments of a tuning duct that is made from a hollow profile can be produced by milling a slot in a transverse direction to the hollow profile and inserting (pressing in) and fixing or welding a partition element, such as a segment plate, preferably made of aluminum. If an extruded section is used, the slot is made into the extruded section, respectively. In this way, two segments can be formed that have a common partition wall.

The advantage of separate segments is that tuning gas can be supplied separately to each segment via at least one tuning duct. Various types of gas can be used as tuning gases to form different chemical compounds in a cathode sputtering process. This separate gas dosing for each segment allows a very flexible design of a deposition process for complex components with different deposition requirements in a large-area design of the components or in the sequence of different layers in the overall structure of a deposit.

The main duct and tuning duct may advantageously comprise a common longitudinal partition wall. Such an embodiment allows a very efficient and inexpensive manufacture of such a component, and multiple functions can be integrated and used in such a component. Such a design is also very useful as a mechanical integration solution for the simplified assembly of the gas distribution apparatus in a deposition plant. It is understood that main duct and tuning duct can also have separate longitudinal partition walls, for example a double wall.

According to an advantageous embodiment, the at least one main gas supply duct can be disposed at an outer region of the main duct wall. It is thus possible to effectively integrate the main gas supply duct into the hollow profile, which can include the main duct and tuning ducts, if any, and manufacture it as a single component. A mechanically stable connection to the main duct is automatically provided in this way, which is a great advantage for efficient assembly.

The at least one tuning gas supply duct can just as expediently be disposed on an outer region of the tuning duct wall. The same advantage of a mechanically stable and at the same time easy to install arrangement of tuning gas supply duct and tuning duct in an integral component that can be inexpensively designed as a hollow profile applies here as well.

In an advantageous embodiment, the at least one main gas supply duct can be connected to the main duct via at least one feed opening in the main duct wall. This allows the creation of a very simple and robust connection, which meets the requirements with respect to mechanical stability and durable sealing.

For example, the feed opening can be designed as a cross hole through the main duct-supply duct into the inner region of the main duct, which cross hole is closed in a section of the wall of the main gas supply duct that does not lead to the main duct. Such a design allows a very simple and inexpensive production of the connection between the main duct-supply duct and the main duct, in that a cross hole is made perpendicular to the hollow profile, which cross hole connects the main duct-supply duct with the main duct and then closes the hole again in the main duct wall towards the outer region.

It is likewise favorable that the at least one tuning gas supply duct can be connected to the tuning duct via at least one feed opening in the tuning duct wall. This allows the creation of a very simple and robust connection, which meets the requirements with respect to mechanical stability and durable sealing.

For example, the feed opening can be designed as a cross hole through the tuning gas supply duct to the inner region of the tuning duct, which cross hole is closed in a section of the wall of the tuning gas supply duct that does Tint lead to the tuning duct. Such a design allows a very simple and inexpensive production of the connection between the tuning duct-supply duct and the tuning duct, in that a cross hole is made perpendicular to the hollow profile, which cross hole connects the tuning duct-supply duct with the tuning duct and then closes the hole again in the tuning duct wall towards the outer region.

It is advantageous that the inner region of the main duct and/or the inner region of the tuning duct has a rectangular cross section. Such a design facilitates the combination of inexpensive production methods and great mechanical stability and ease of installation, since rectangular cross sections fit better to flat surfaces and can be installed in a space-saving manner. It is understood that the inner region of main duct and/or the inner region of the tuning duct can have other cross sections, such as circular or oval cross sections.

According to an advantageous embodiment, the gas conducting device can comprise a region associated with the inner region of the vacuum chamber and a region associated with the chamber wall of the vacuum chamber, and at least one first tuning gas supply duct can be disposed in the region associated with the inner region of the vacuum chamber and a second tuning gas duct can be disposed in the region associated with the chamber wall of the vacuum chamber. In this way, as many tuning gas supply ducts as possible can be provided on a tuning duct. It can further be expedient to have a tuning gas supply duct available directly in the inner region of the vacuum chamber, for example to introduce tuning gas directly from the tuning gas supply duct into the vacuum chamber. It may also be advantageous for the temperature control of tuning gases to provide these tuning gas supply ducts on a region connected to the outer wall of the vacuum chamber, such that the tuning gas can be temperature-controlled via the wall.

### BRIEF DESCRIPTION OF THE DRAWINGS

Other advantages can be derived from the following description of the drawings. The drawings show embodiments of the invention. The drawings, the description, and the claims contain numerous features in combination. A person skilled in the art will expediently consider these features individually and group them into useful other combinations.

FIG. 1 shows a cross section of a gas distribution apparatus comprising a main duct and a tuning duct according to an embodiment of the invention, which are disposed in a section of a vacuum chamber; and

FIG. 2 shows an isometric view of a gas distribution apparatus according to an embodiment of the invention consisting of or comprising two hollow profiles whose supply ducts are connected by feed lines.

### DETAILED DESCRIPTION

The same or similar components are assigned the same reference symbols in the figures. The figures merely show examples and are not to be considered limiting.

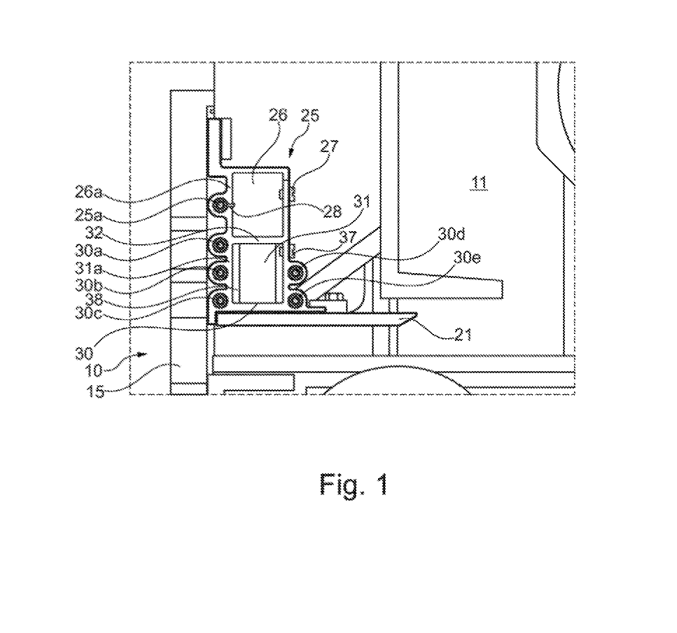

FIG. 1 shows a cross section of a gas distribution apparatus comprising a main duct and a tuning duct according to an embodiment of the invention, which are disposed in a section of a vacuum chamber 10. The gas distribution apparatus of a vacuum chamber 10 comprising a gas conducting device includes as gas carrying ducts a main duct 25 with main duct nozzles 27, from which a main gas can be distributed into the vacuum chamber 10, as well as a tuning duct 30 with tuning duct nozzles 37, 37′, from which at least one tuning gas can be distributed into the vacuum chamber 10. The gas distribution apparatus further includes a gas supplying device with a main gas supply duet 25a, by means of which the main gas is to be supplied the main duct 25, and tuning gas ducts 30a, 30b, 30c, 30d, 30e, by means of which the tuning gas is to be supplied to the tuning duct 30. The main duct 25 is formed of a component 20 designed as a single-piece hollow profile, wherein the main gas supply duct 25a and the tuning gas supply ducts 30a, 30b, 10c, 30d, 30e are also formed of the component 20 designed as a single-piece hollow profile. The component 20 is preferably designed as an extruded section. The one tuning duct 30 is also formed of the component 20 designed as a single-piece hollow profile. Since the main duct 25 and the tuning duct 30 are arranged directly on top of one another, they comprise a common longitudinal partition wall 32. The main gas supply duct 25a is disposed on an outer region of a main duct wall 26a and lies against the chamber wall 15 of the vacuum chamber 10. The tuning gas supply ducts 30a, 30b, 30c are likewise disposed on the outer region of the tuning duct wall 31a and lie against the chamber wall 15 as well. In another embodiment, the main gas supply duct and/or the tuning gas supply ducts do not lie against the chamber wall.

The inner legion 26 of the main duct 25 and the inner region 31 of the tuning duct 30 have a rectangular cross section. The gas supplying device comprises a region associated with the inner region 11 of the vacuum chamber 10 and a region associated with the chamber wall 15 of the vacuum chamber 10. The tuning gas supply ducts 30d, 30e are disposed in the region associated with the inner region 11 of the vacuum chamber 10 and the tuning gas supply ducts 30a, 30b, 30c are disposed in the region associated with the chamber wall 15 of the vacuum chamber 10.

The main gas supply duct 25a is connected to the main duct 25 via at least one feed opening 28 or via multiple feed openings 28 in the main duct wall 26a, wherein the feed opening 28 is designed as a cross hole extending through the main duct-supply duct 25a to the inner region 26 of the main duct, which is closed in a region in the wall of the main gas supply duct 25a that is not leading to the main duct 25. The tuning gas supply ducts 30a, 30b, 30c, 30d, 30e are likewise connected to the tuning duct 30 via at least one feed opening 38 or via multiple feed openings 38 in the tuning duct wall 31a, wherein the feed opening 38 is designed as across hole extending through the tuning gas supply ducts 30a, 30b, 30c, 30d, 30e to the inner region 26 of the tuning duct 30, which are closed in a region in the wall of the tuning gas supply ducts 30a, 30b, 30c, 30d, 30e that is not leading to the tuning duct 30. FIG. 1 shows a feed opening 38 of the tuning gas supply duct 30b in the drawing plane. The feed openings of the other timing gas supply ducts 30a, 30c, 30d, 30e are located in other drawing planes of the representation of the gas distribution apparatus.

A guide plate 21 which can cause a favorable flow of the gases when they exit from the main duct 25 or the tuning duct 30 into the vacuum chamber 10, is disposed perpendicular to the chamber wall 15 and resting against the bottom side of the tuning duct 30. The drawing plane of FIG. 1 shows a main duct nozzle 27 via which the main gas can flow into the vacuum chamber 10 in a wall of the main duct 25 towards the inner region 11 of the vacuum chamber 10, and a tuning duct nozzle 37 via Which the tuning gas can flow into the vacuum chamber 10. Other main duct nozzles 27 via which the main gas and tuning gas nozzles 37 via which the tuning gas can flow into the vacuum chamber 10 are located in other planes.

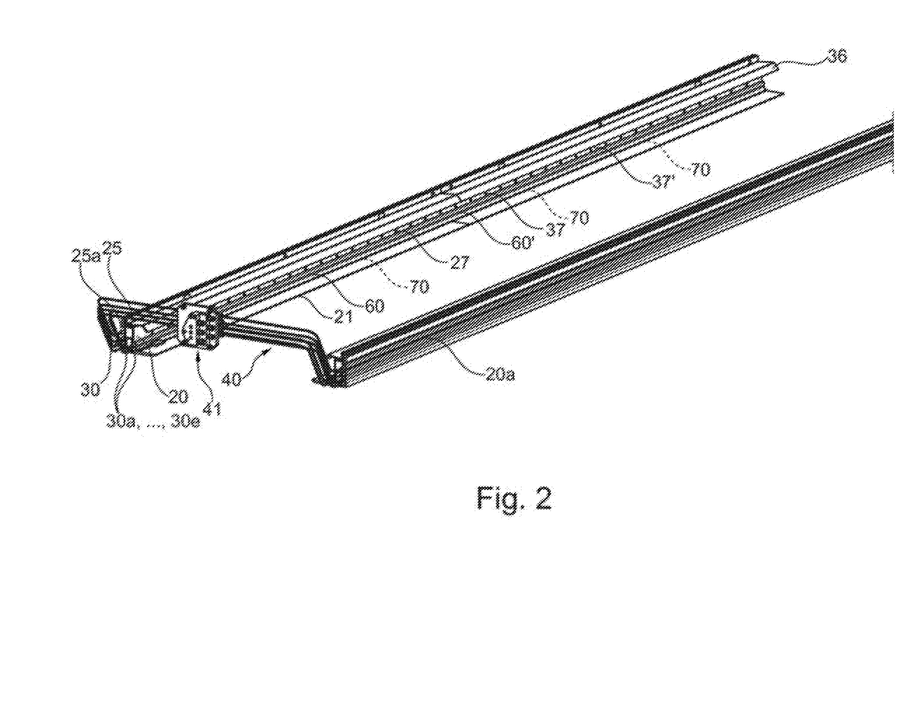

FIG. 2 is an isometric view of a gas distribution apparatus according to an embodiment of the invention consisting of two single-piece components 20, 20a in the form of hollow profiles, whose gas supply ducts 25a, 30a, 30b, 30c, 30d, 30e are connected by feed lines 40, The feed lines 40 are conducted through a vacuum feedthrough 41 into a vacuum chamber 10 (not shown) and feed the two main ducts 25 and the tuning ducts 30 of the two components 20, 20a of the gas distribution apparatus simultaneously. A tuning duct 30 of the gas distribution apparatus includes multiple chamber-like segments 60, 60′ arranged one after the other, wherein two single-piece segments 60, 60′ have a common transverse partition wall 70 or a segment plate, respectively.

The advantage of dividing the tuning duct 30 into segments 60, 60′ is that each segment 60, 60′ can be separately supplied with tuning gas via at least one tuning gas supply duct 30a, 30b, 30c, 30d, 30e. Such an arrangement has the advantage that the tuning gases can be introduced into the various regions of the vacuum chamber 10 in a targeted manner to achieve completely different deposition conditions at different spots while depositing onto a substrate. In this way, different deposition parameters or even different materials can be used at different spots. It is also possible to achieve different layer thicknesses or different layer properties in an inexpensive manner. The gas distribution apparatus can be designed for a larger number of segments depending on the requirements to be met by the layer distribution. Various types of gas can be used as tuning gases to form different chemical compounds in a cathode sputtering process. This separate gas dosing for each segment 60, 60′ allows a very flexible design of a deposition process for complex components with different deposition requirements in a large-area design of the components or in the sequence of different layers in the overall structure of a deposit.

Gas conduction in the vacuum chamber can be designed as suitable using the guide plates 21 and 36. The main gas can flow from the main duct 25 via the main duct nozzles 27, the tuning gas can flow from the tuning duct 30 via the tuning duct nozzles 37 into the vacuum chamber 10 and can be conducted as suitable there, even in a vacuum, using the guide plates 21 and 36.

### LIST OF REFERENCE SYMBOLS

10 Vacuum chamber

11 inner region of the vacuum chamber

15 Chamber wall

20 Component

20a Component

21 Guide plate

25 Main duct

25a Main gas supply duct

26 Inner region of the main duct

26a Main duct wall

27 Nozzle

28 Feed opening

30 Tuning duct

30a Tuning gas supply duct

30b Tuning gas supply duct

30c Tuning gas supply duct

30d Tuning gas supply duct

30e Tuning gas supply duct

31 Inner region of the tuning duct

31a Tuning duct wall

32 Longitudinal partition wall

36 Guide plate

37 Nozzle

37′ Nozzle

38 Feed opening

40 Feed lines

41 Vacuum feed nigh

60 Segment

60′ Segment

70 Transverse partition wall, segment plate

1-16. (canceled)

17. A gas distribution apparatus of a vacuum chamber comprising a gas conducting device having at least one main duct that includes nozzles from which gas can be distributed into the vacuum chamber and comprising a gas supplying device with which gas can be supplied to the gas conducting device, wherein the at least one main duct is formed by a single-piece component designed as a hollow profile, and at least one main gas supply duct of the gas supplying device and at least one tuning duct with tuning duct nozzles from which tuning gas can be distributed into the vacuum chamber is also formed by the single-piece component designed as a hollow profile, wherein the component is designed as an extruded section.

18. The gas distribution apparatus of a vacuum chamber comprising a gas conducting device according to claim 17, wherein at least one tuning gas supply duct is also formed by the single-piece component designed as a hollow profile.

19. The gas distribution apparatus according to claim 17, wherein the at least one tuning duct includes multiple chamber-like segments arranged one after the other along a longitudinal extension of the duct.

20. The gas distribution apparatus according to claim 19, wherein at least two consecutive segments have a common transverse partition wall.

21. The gas distribution apparatus according to claim 19, wherein tuning gas is or can be supplied to each segment via at least one tuning gas supply duct.

22. The gas distribution apparatus according to at least one of claims 18, wherein the main duct and the tuning duct have a common longitudinal partition wall.

23. The gas distribution apparatus according to claim 18, wherein the at least one main gas supply duct is disposed on an outer region of a main duct wall.

24. The gas distribution apparatus according claim 18, wherein the at least one tuning gas supply duct is disposed on an outer region of the. tuning duct wall.

25. The gas distribution apparatus according to claim 23, wherein the at least one main gas supply duct is connected to the main duct via at least one feed opening in the main duct wall.

26. The gas distribution apparatus according to claim 25, wherein the feed opening can be designed as a cross hole through the main duct-supply duct into the inner region of the main duct, which cross hole is closed in a section of the wall of the main gas supply duct that does not lead to the main duct.

27. The gas distribution apparatus according to claim 24, wherein the at least one tuning gas supply duct is connected to the tuning duct via at least one feed opening in the tuning duct wall.

28. The gas distribution apparatus according to claim 27, wherein the feed opening can be designed as a cross hole through the tuning gas supply duct into the inner region of the timing duct, which cross hole is closed in a section of the wall of the tuning gas supply duct that does not lead to the tuning duct.

29. The gas distribution apparatus according to claim 18, wherein the inner region of the main duct and/or the inner region of the tuning duct have a rectangular cross section.

30. The gas distribution apparatus according to claim 18, wherein the gas conducting device has a region associated with the inner region of the vacuum chamber and a region associated with the chamber wall of the vacuum chamber, and at least one first tuning gas supply duct is disposed in the region associated with the inner region of the vacuum chamber and a second tuning gas duct is disposed in the region associated with the chamber wall of the vacuum chamber.
